(19) United States
(12) Patent Application Publication
(10) Pub. No.: US 2024/0352316 A1
(43) Pub. Date: Oct. 24, 2024

(54) METHOD OF FORMING QUANTUM-DOT LAYER, QUANTUM-DOT LAYER, OPTICAL ELEMENT, AND LIGHT-EMITTING DEVICE

(71) Applicant: Sharp Display Technology Corporation, Kameyama City, Mie (JP)

(72) Inventor: Yukio TAKENAKA, Kameyama City, Mie (JP)

(21) Appl. No.: 18/686,433

(22) PCT Filed: Oct. 19, 2021
(86) PCT No.: PCT/JP2021/038610

§ 371 Date: Feb. 26, 2024

(51) Int. Cl. C09K 11/88; B05D 3/02; B05D 3/06; H01L 33/50

(52) U.S. Cl. CPC C09K 11/883; B05D 3/0254; B05D 3/065; H01L 33/502

(57) ABSTRACT

A method of forming a quantum-dot layer containing at least one quantum dot and a metal sulfide includes: a step of preparing a quantum-dot-dispersed solution in which the quantum dots are dispersed in a liquid containing halide ions and a precursor to the metal sulfide; and a step of applying the quantum-dot-dispersed solution to a substrate.

### TECHNICAL FIELD

The present invention relates to a quantum-dot layer, an optical element including the quantum-dot layer, and a light-emitting device including the optical element as a light-emitting element.

### BACKGROUND ART

Non-Patent Literature 1 discloses sulfide-protected quantum dots.

### CITATION LIST

### Non-Patent Literature

Non-patent Literature 1: InP-Quantum-Dot-in-ZnS-Matrix Solids for Thermal and Air Stability, Chemical Material, 2020, 32, 22, 9584-9590

### SUMMARY OF INVENTION

### Technical Problem

Sulfide-protected quantum dots in a solution, when let to sit, may aggregate, which can be a cause for an irregular thickness of a quantum-dot layer formed from these quantum dots.

### Solution to Problem

To address this issue, the present invention, in one aspect thereof, is directed to a method of forming a quantum-dot layer containing at least one quantum dot and a metal sulfide, the method including: a step of preparing a quantum-dot-dispersed solution in which the at least one quantum dot is dispersed in a liquid containing halide ions and a precursor to the metal sulfide; and a step of applying the quantum-dot-dispersed solution to a substrate.

The present invention, in one aspect thereof, is directed to a quantum-dot layer including: a metal sulfide including a continuous film with a 1,000 nm² or greater area in an in-plane direction perpendicular to a thickness direction of the quantum-dot layer in a location along the thickness direction; and at least one quantum dot encased in the metal sulfide and having a different composition than the metal sulfide, wherein the quantum-dot layer has a thickness that has a maximum value less than or equal to twice a minimum value of the thickness.

The present invention, in another aspect thereof, is directed to a quantum-dot layer including: at least one quantum dot; a metal sulfide; and halogen atoms, wherein the halogen atoms have an average concentration that is higher by at least 10% within 1 nm from an outermost face of the at least one quantum dot than in other locations.

### Advantageous Effects of Invention

The present invention, in one aspect thereof, provides a quantum-dot layer with reduced thickness irregularity while protecting quantum dots with a metal sulfide.

### BRIEF DESCRIPTION OF DRAWINGS

FIG. 1 is a schematic cross-sectional view of a light-emitting device in accordance with Embodiment 1 of the present invention.

FIG. 2 is a schematic enlarged view of a quantum dot and its surroundings shown in the schematic cross-sectional view of the light-emitting device in accordance with Embodiment 1 of the present invention.

FIG. 3 is a flow chart representing a method of manufacturing the light-emitting device in accordance with Embodiment 1 of the present invention.

FIG. 4 is a step-specific side view illustrating a method of replacing ligands coordinated to quantum dots in accordance with Embodiment 1 of the present invention.

FIG. 5 is a schematic diagram representing a quantum-dot-dispersed solution in accordance with Embodiment 1 of the present invention.

FIG. 6 is a step-specific cross-sectional view illustrating a method of forming a light-emitting layer in accordance with Embodiment 1 of the present invention.

FIG. 7 is a pair of graphs representing the flatness of the light-emitting layer in accordance with an example of the present invention, in comparison with a light-emitting layer in accordance with a comparative example.

FIG. 8 is a schematic cross-sectional view of a display device in accordance with Embodiment 2 of the present invention.

FIG. 9 is a flow chart representing a method of manufacturing the display device in accordance with Embodiment 2 of the present invention.

FIG. 10 is a step-specific cross-sectional view illustrating a method of forming a light-emitting layer in accordance with Embodiment 2 of the present invention.

FIG. 11 is another step-specific cross-sectional view illustrating the method of forming the light-emitting layer in accordance with Embodiment 2 of the present invention.

FIG. 12 is another step-specific cross-sectional view illustrating the method of forming the light-emitting layer in accordance with Embodiment 2 of the present invention.

FIG. 13 is another step-specific cross-sectional view illustrating the method of forming the light-emitting layer in accordance with Embodiment 2 of the present invention.

FIG. 14 is a schematic cross-sectional view of a display device in accordance with Embodiment 3 of the present invention.

FIG. 15 is a schematic cross-sectional view of a light-emitting device in accordance with Embodiment 4 of the present invention.

FIG. 16 is a flow chart representing a method of manufacturing the light-emitting device in accordance with Embodiment 4 of the present invention.

### DESCRIPTION OF EMBODIMENTS

### Embodiment 1

### Overview of Light-Emitting Device

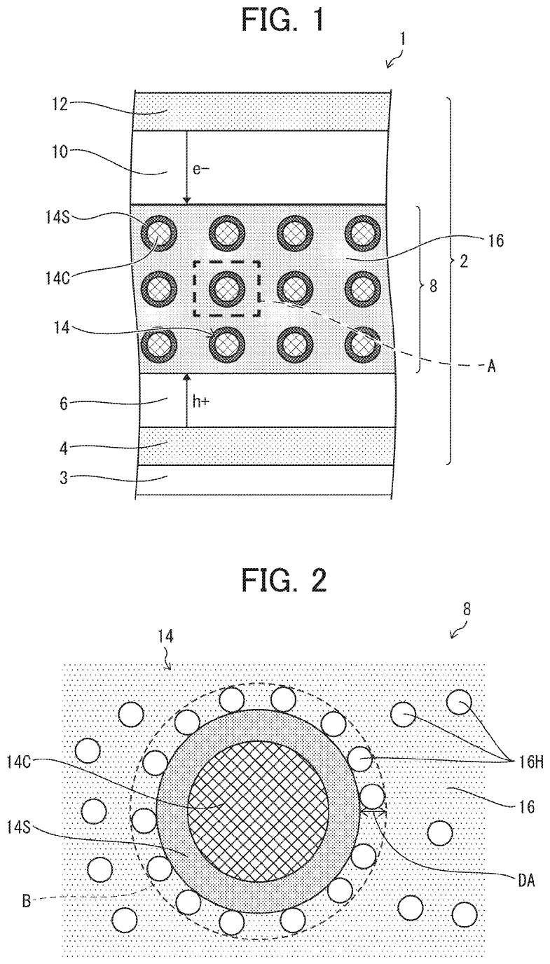

FIG. 1 is a schematic cross-sectional view of a light-emitting device, which is an example of an optical device in accordance with an embodiment of the present invention. Referring to FIG. 1, a light-emitting device 1 in accordance with the present embodiment includes a light-emitting element 2 and an array substrate 3. The light-emitting device 1 has a structure in which various layers of the light-emitting element 2 are stacked on the array substrate 3 carrying a TFT (thin film transistor; not shown) formed thereon. Note that in the present specification, the direction from the light-emitting element 2 toward the array substrate 3 in the light-emitting device 1 is referred to as “downward,” and the direction opposite this downward direction is referred to as “upward.”

The light-emitting element 2 includes a hole transport layer 6, a light-emitting layer 8, an electron transport layer 10, and a cathode 12 (second electrode), all of which are provided on an anode 4 (first electrode) in this order when viewed upward. The anode 4 in the light-emitting element 2 overlies the array substrate 3 and is electrically connected to the TFT on the array substrate 3.

### Overview of Light-Emitting Element

The following will describe each layer in the light-emitting element 2 in more detail.

The anode 4 and the cathode 12 contain a conductive material and are electrically connected respectively to the hole transport layer 6 and the electron transport layer 10.

Either or both of the anode 4 and the cathode 12 is (are) a transparent electrode that transmits visible light. The transparent electrode may be made of, for example, ITO, IZO, ZnO, AZO, BZO, or FTO and formed by, for example, sputtering. In addition, either or both of the anode 4 and the cathode 12 may contain a metal material that is preferably Al, Cu, Au, Ag, or Mg, which has a high reflectance to visible light, either singly or in the form of an alloy.

The hole transport layer 6 transports holes from the anode 4 to the light-emitting layer 8. The hole transport layer 6 can be made of an organic or inorganic material conventionally used in, for example, quantum-dot-containing light-emitting elements and organic EL light-emitting elements. The organic material for the hole transport layer 6 may be an electrically conductive compound such as CBP, PPV, PEDOT-PSS, TFB, or PVK. The inorganic material for the hole transport layer 6 may be a metal oxide such as molybdenum oxide, NiO, Cr₂O₃, MgO, MgZnO, LaNiO₃, or WO₃. The hole transport layer 6 is particularly preferably made of a material that has a high electron affinity and a high ionization potential.

The electron transport layer 10 transports electrons from the cathode 12 to the light-emitting layer 8. The electron transport layer 10 may be made of TiO₂ or an organic or inorganic material conventionally used in, for example, quantum-dot-containing light-emitting elements and organic EL light-emitting elements. The organic material for the electron transport layer 10 may be an electrically conductive compound such as Alq3, BCP, or t-Bu-PBD. The inorganic material for the electron transport layer 10 may be a metal oxide such as ZnO, ZAO, ITO, IGZO, or electride. The electron transport layer 10 is particularly preferably made of a material that ha a low electron affinity.

In the present embodiment, the hole transport layer 6 and the electron transport layer 10 are formed by vacuum vapor deposition or sputtering using the aforementioned materials or coating with a colloidal solution. In addition, the light-emitting element 2 may include a hole injection layer between the anode 4 and the hole transport layer 6 and may include an electron injection layer between the cathode 12 and the electron transport layer 10. The light-emitting element 2 may further include an intermediate layer between the hole transport layer 6 and the light-emitting layer 8 or between the electron transport layer 10 and the light-emitting layer 8. Any of these hole injection layer, electron injection layer, and intermediate layer may be formed by the same method as the hole transport layer 6 or the electron transport layer 10.

### Light-Emitting Layer (Quantum-Dot Layer)

In the present embodiment, the light-emitting layer 8 includes at least one quantum dot 14 and a sulfide semiconductor 16 as a metal sulfide. In other words, the light-emitting layer 8 in accordance with the present embodiment is a quantum-dot layer. Each quantum dot 14 has, for example, a core/shell structure including a core 14C and a shell 14S formed around the core 14C. In the present embodiment, electrons and holes fed to the quantum dots 14 recombine primarily in the core 14C. The shell 14S serves to restrain, for example, generation of defects and dangling bonds in the core 14C and to reduce recombination of carriers through a deactivation process.

The quantum dots 14 may contain materials used as core and shell materials for conventional, publicly known core/shell-structured quantum dots as the materials for the cores 14C and the shells 14S respectively.

For instance, in the present embodiment, a material for the shell 14S contains ZnSₓSe₁₋ₓ where 0≤x≤1. Specifically, the quantum dots 14 may be, for example, Cd-based semiconductor nanoparticles with a CdSe-containing core 14C and a ZnS-containing shell 14S. Alternatively, the quantum dots 14 may be, for example, Cd-based semiconductor nanoparticles with a CdSe-containing core 14C and a ZnSe-containing shell 14S.

Apart from these examples, the quantum dots 14 may contain, for example, CdSe/CdS, InP/ZnS, ZnSe/ZnS, or CIGS/ZnS in their core/shell structure. Note that the shell 14S may include a plurality of layers of mutually different materials.

The core 14C of the quantum dot 14 is a light-emitting material that has a valence band energy level and a conduction band energy level such as to emit light upon recombination of holes in the valence band energy level and electrons in the conduction band energy level. The emission of the quantum dot 14 has such a small spectrum due to the quantum confinement effect as to exhibit relatively deep chromaticity.

In the current context, as shown in FIG. 1, the quantum dots 14 in the light-emitting layer 8 do not need to be arranged regularly and may be randomly contained in the light-emitting layer 8. In addition, FIG. 1 shows the light-emitting layer 8 as containing the sulfide semiconductor 16 (detailed later) between every two quantum dots 14 so that the quantum dots 14 are not in contact with each other. As an alternative to this, the light-emitting layer may contain two or more quantum dots 14 that are in contact with each other. Note that the light-emitting layer 8 may have a thickness of approximately from 1 nm to 100 nm.

The quantum dots 14 have a particle diameter of approximately from 1 to 100 nm. The wavelength of the emission of the quantum dots 14 is controllable through the particle diameter. Particularly, since the quantum dots 14 have a core/shell structure, the wavelength of the emission of the quantum dots 14 is controllable through the control of the particle diameter of the cores 14C. Therefore, the wavelength of the light discharged by the light-emitting device 1 is controllable through the control of the particle diameter of the cores 14C of the quantum dots 14.

In the present embodiment, the sulfide semiconductor 16 contained in the light-emitting layer 8 is, for example, ZnS (zinc sulfide), ZnTeS, ZnMgS₂, MgS, Ga₂S₃, ZnGa₂S₄, or MgGa₂S₄. In particular, in in the present embodiment, the light-emitting layer 8 is a film in which the ZnS-containing sulfide semiconductor 16 is integrated with the quantum dots 14. Hence, the sulfide semiconductor 16 can protect the quantum dots 14, which improves the reliability of the light-emitting layer 8. For example, in the light-emitting layer 8, the sulfide semiconductor 16 may be formed so as to fill spaces formed between the plurality of quantum dots 14.

It should be understood however that the light-emitting layer 8 may contain a metal oxide or metal sulfide other than the sulfide semiconductor 16, provided that the feeding of carriers from each charge transport layer to the quantum dots 14 and the transmission of visible light are not inhibited. The metal oxide or metal sulfide other than the sulfide semiconductor 16 may account for less than 50 atom %, more preferably less than or equal to 30 atom %, and more preferably less than or equal to 10 atom % of the light-emitting layer 8.

The sulfide semiconductor 16 in accordance with the present embodiment includes a continuous film with a 1,000 nm² or greater area in an in-plane direction perpendicular to the thickness direction of the light-emitting layer 8 in a location along the thickness direction. In addition, in the light-emitting layer 8, the quantum dots 14 are encased by the continuous film in the sulfide semiconductor 16. Note that the quantum dots 14 have a different composition than the sulfide semiconductor 16.

For instance, when 60% or more of the surface of 80% or more of the quantum dots 14 in the light-emitting layer 8 is in contact with the continuous film in the sulfide semiconductor 16, the quantum dots 14 in the light-emitting layer 8 may be described as being encased by the sulfide semiconductor 16. The light-emitting layer 8 containing such quantum dots 14 encased by the sulfide semiconductor 16 has improved luminescence properties and an extended life.

The light-emitting layer 8 contains one or more quantum dots 14 per 1,000 nm² in an in-plane direction perpendicular to the thickness direction in a location along the thickness direction. Therefore, the light-emitting layer 8 contains a sufficient concentration of quantum dots 14 to serve generally as a light-emitting layer in a light-emitting element.

The light-emitting layer 8 has an average thickness of from 10 nm to 100 nm, both inclusive. In addition, the thickness of the light-emitting layer 8 has a maximum value that is less than or equal to twice its minimum value. Particularly, the light-emitting layer 8 has a surface-roughness RMS of less than or equal to 3 nm. Here, the average roughness RMS of the light-emitting layer 8 is the square root of a value obtained by averaging the squares of deviations from an average line of the surface at any of two thickness-wise ends of the light-emitting layer 8. Therefore, a smaller average roughness RMS of the light-emitting layer 8 indicates that the light-emitting layer 8 is flatter/smoother. To reduce variations in carrier injection efficiency caused by the location of the light-emitting layer, it is generally more preferred if the light-emitting layer of a light-emitting element is flatter/smoother. When the thickness of the light-emitting layer 8 has a maximum value that is less than or equal to twice its minimum value, the light-emitting layer 8 has such a flatness/smoothness as to sufficiently serve as a light-emitting layer in a light-emitting element. In addition, when the light-emitting layer 8 has a surface-roughness RMS of less than or equal to 3 nm, the light-emitting layer 8 exhibits more desirable luminescence properties as a light-emitting layer in a light-emitting element.

Referring to FIG. 2, a more detailed description is given of the quantum dots 14 and their surroundings in the light-emitting layer 8 of the present embodiment. FIG. 2 is a schematic enlarged view of one of the quantum dots 14 and its surroundings shown in in the schematic cross-sectional view of FIG. 1.

In the present embodiment, the light-emitting layer 8 contains halide ions 16H including at least one species of fluoride ions, chloride ions, bromide ions, and iodide ions. In the current context, in the light-emitting layer 8, the halide ions 16H have a higher concentration in the vicinity of each quantum dot 14 than in the spaces surrounding the vicinity.

For instance, as shown in FIG. 2, DA is defined as a distance from the exterior face of the shell 14S that is the outermost face of the quantum dot 14 on the periphery of the quantum dot 14. Here, when distance DA is equal to 1 nm, the vicinity of the quantum dot 14 may be defined as referring to up to distance DA from the outermost face of the quantum dot 14.

The halide ions 16H in the vicinity of the quantum dot 14 may be coordinately bonded to the shell 14S of the quantum dot 14. Assume that, as an example, the light-emitting layer 8 is formed by coating with a dispersion of the quantum dots 14 (detailed later). In such a case, the halide ions 16H coordinated to the shell 14S of the quantum dots 14 in the solution are likely to be the halide ions 16H in the vicinity of the quantum dots 14 in the light-emitting layer 8. In the present embodiment, the light-emitting layer 8 contains not more than 5 atom % carbon atoms. In addition, in the present embodiment, the light-emitting layer 8 contains at least 1 atom % halogen atoms.

In the present embodiment, the halogen atoms within 1 nm from the outermost face of the quantum dot 14 may have a 10%, 50%, or 100% higher average concentration than do the halogen atoms in other locations.

In addition, the sulfide semiconductor 16 in the light-emitting layer 8 may have a larger band gap than does the material for the core 14C of the quantum dot 14. When this is the case, the excitons generated by the recombination of carriers or the absorption of light in the core 14C of the quantum dot 14 are less likely to diffuse into the sulfide semiconductor 16, which renders the luminescence properties of the quantum dot 14 less likely to be inhibited.

When the light-emitting layer 8 is formed from a quantum-dot-dispersed solution containing the quantum dots 14 (detailed later), a drying step of drying this quantum-dot-dispersed solution by heating may be involved. Here, in the drying step, for example, a stack body containing the quantum-dot-dispersed solution applied onto the hole transport layer 6 is heated to a temperature of from 80°° C. to 500° C. Therefore, in the present embodiment, all the layers in the light-emitting element 2 from the anode 4 through the cathode 12 may be each composed of a layer of an inorganic material with a view to the heat-resistance of the light-emitting element 2.

### Overview of Method of Manufacturing Light-Emitting Device

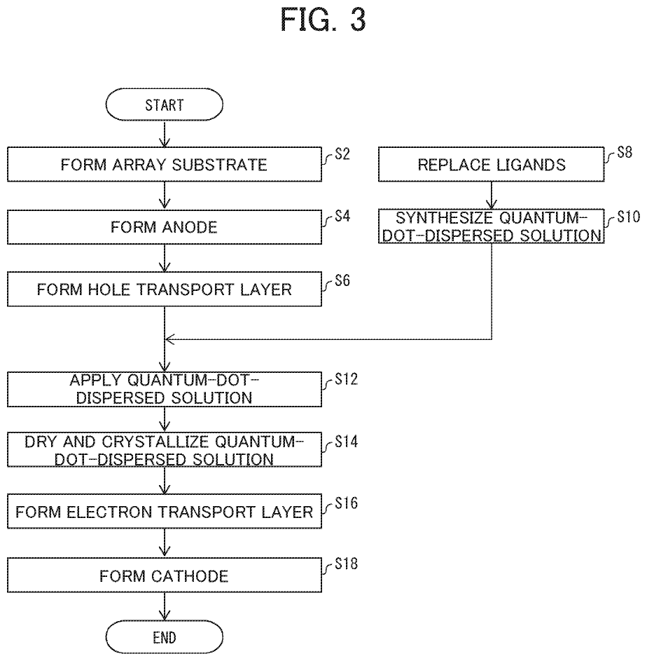

Referring to FIG. 3, a description is now given of a method of manufacturing the light-emitting device 1 that is an exemplary method of manufacturing an optical device in accordance with the present embodiment. FIG. 3 is a flow chart representing a method of manufacturing the light-emitting device 1 in accordance with the present embodiment.

In the method of manufacturing the light-emitting device 1 in accordance with the present embodiment, first of all, the array substrate 3 is formed (step S2). The array substrate 3 may be formed by forming TFTs on a glass substrate in accordance with the position where the anode 4 is formed in the light-emitting element 2.

Next, the anode 4 is formed (step S4). The anode 4 may be formed by, for example, forming a film of a conductive material by, for example, sputtering as described above. Next, the hole transport layer 6 is formed (step S6). The hole transport layer 6 may be formed by, for example, vacuum vapor deposition, sputtering, or coating with a colloidal solution as described above.

### Synthesis of Quantum-Dot-Dispersed Solution

Next, the light-emitting layer 8 is formed. The present embodiment gives an example where the light-emitting layer 8 is obtained by synthesizing a quantum-dot-dispersed solution containing the quantum dots 14, applying this quantum-dot-dispersed solution, and subsequently drying the quantum-dot-dispersed solution.

In the present embodiment, the aforementioned quantum-dot-dispersed solution is, for example, a solution containing the quantum dots 14 to which the halide ions 16H are coordinated. Therefore, in the present embodiment, for example, a step of obtaining the quantum dots 14 to which the halide ions 16H are coordinated is performed as a, pre-process of the step of synthesizing a quantum-dot-dispersed solution containing the quantum dots 14. More specifically, a replacing step of replacing the ligands coordinated to the quantum dots 14 (step S8) is performed.

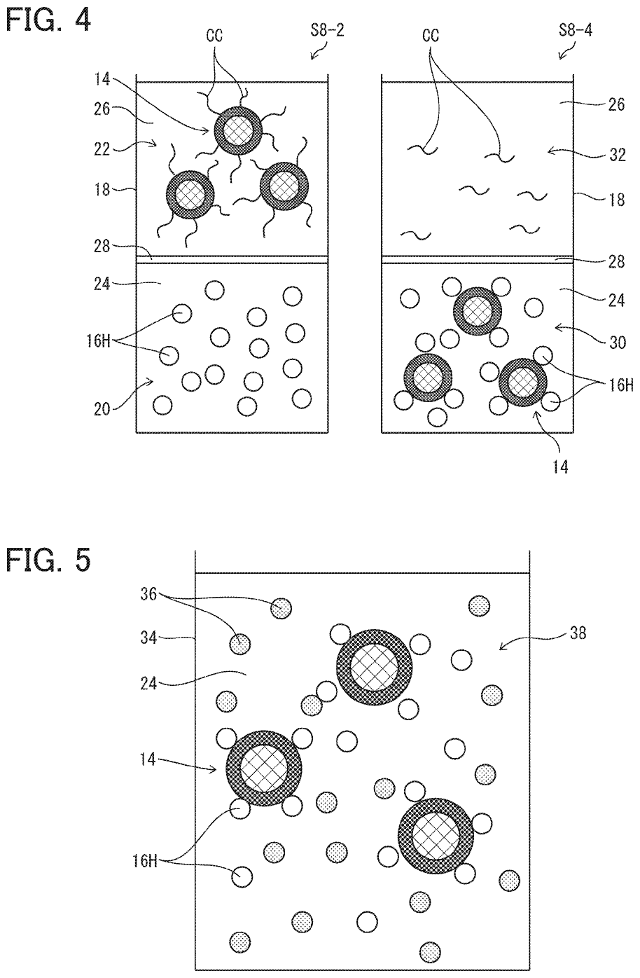

FIG. 4 is a step-specific cross-sectional view illustrating this replacing step. As shown in step S8-2 in FIG. 4, in the replacing step, first of all, a first solution 20 in which the halide ions 16H are dissolved and a second solution 22 in which the quantum dots 14, to which carbon chains CC as organic ligands are coordinated, are dispersed are fed into a container 18. The first solution 20 contains a first medium 24 in which the halide ions 16H are soluble, and the second solution 22 contains a second medium 26 in which the carbon chains CC are soluble. For example, the second medium 26 has a different polarity than the first medium 24 and a smaller specific gravity than the first medium 24. A separation solution 28 that has a specific gravity and a polarity between those of the first medium 24 and the second medium 26 may be fed into the container 18 to more clearly distinguish the boundary between the first solution 20 and the second solution 22.

The first medium 24 may contain at least one of, for example, dimethyl sulfoxide (DMSO), N,N-dimethylformamide (DMF), N-methylformamide (NMF), formamide, N,N′-dimethylpropylene urea, dimethylacetamide, N-methylpyrrolidone, y-butyrolactone, propylene carbonate, acetonitrile, 2-methoxyethanol, methyl acetate, ethyl acetate, ethyl formate, methyl formate, tetrahydrofuran, diethyl ether, tetrahydrothiophene, and diethyl sulfide. In such cases, the first medium 24 disperses well both the quantum dots 14 to which the halide ions 16H are coordinated and a precursor to the sulfide semiconductor 16 (detailed later). In addition, the first medium 24 may be a polar solvent that has greater polarity than the second medium 26. The first medium 24 may be prepared by dispersing, for example, zinc chloride, sodium chloride, or hydrochloride in, for example, NMF, DMF, or DMSO. The second medium 26 is preferably, for example, toluene, hexane, octane, or octadecene. In other words, the second medium 26 is preferably a non-polar solvent that is not miscible with the first medium 24.

The carbon chain CC may be a carbon chain used generally as ligands for the quantum dots 14. Since the carbon chains CC are soluble in the second medium 26, the quantum dots 14 to which the carbon chains CC are coordinated easily disperse in the second solution 22. In addition, the first solution 20 dissolves the halide ions 16H in an excess amount that exceeds the amount of the halide ions 16H that can be coordinated to the quantum dots 14. The first medium 24 has a halide ion concentration of, preferably greater than or equal to 0.01 mol/l and more desirably greater than or equal to 0.1 mol/l.

Next, the first solution 20 and the second solution 22 are stirred by shaking the container 18 containing the first solution 20 and the second solution 22 described above at high frequency in a stirrer. The container 18 may be provided with a stirring bar for improved stirring efficiency. In other words, the step of stirring the first solution 20 and the second solution 22 is a step of processing the quantum dots 14 with the halide ions 16, and in particular a step of producing the quantum dots 14 to which the halide ions 16 are coordinated.

Here, as described above, the first solution 20 contains the halide ions 16H in an excess amount. Generally, when the solution in which the quantum dots 14 are dispersed contains two or more types of ligands, the ligands coordinated to these quantum dots 14 are in equilibrium with the ligands contained in the solution. Therefore, at least some of the ligands coordinated to the quantum dots 14 change from the carbon chains CC to the halide ions 16H upon stirring the first solution 20 and the second solution 22.

For instance, in step S8, the solution in the container 18 is stirred at least 1 minute. In addition, the solution in the container 18 may be stirred 1 hour by shaking 10 times per minute while keeping the temperature of the solution in the container 18 at 25° C. Under these conditions, the ligands coordinated to the quantum dots 14 in the container 18 are sufficiently likely to be replaced by the halide ions 16H. Furthermore, to prevent, for example, moisture or oxygen in the atmosphere from being mixed with the solution in the container 18, the solution in the container 18 is more preferably stirred in a nitrogen, argon, or like atmosphere.

Therefore, as a result of the aforementioned stirring, a third solution 30 in which the quantum dots 14 to which the halide ions 16H are coordinated are dispersed in the first medium 24 and a fourth solution 32 in which the carbon chains CC are dissolved in the second medium 26 are obtained in the container 18 as shown in step S8-4 in FIG. 4. The quantum dots 14 to which the halide ions 16H are coordinated are hence obtained in the third solution 30. Note that the stirring may be considered complete when it is verified that the liquid layer that glows under, for example, ultraviolet light in the container 18 has moved down inside the container 18.

Next, a quantum-dot-dispersed solution is synthesized in which the quantum dots 14 to which the aforementioned halide ions 16H are coordinated are dispersed (step S10). The quantum-dot-dispersed solution in accordance with the present embodiment is described in detail with reference to FIG. 5. FIG. 5 is a schematic diagram representing the quantum-dot-dispersed solution synthesized in step S10. In step S10, for example, following foregoing step S8, only the third solution 30 is extracted from the container 18 using, for example, a dropper and fed into a container 34 shown in FIG. 5.

Here, a solution in which a precursor 36 to the sulfide semiconductor 16 is dispersed in the first medium 24 may be fed into the container 18 in advance. Therefore, in step S10, a quantum-dot-dispersed solution 38 is synthesized in which the quantum dots 14 to which the halide ions 16H are coordinated and the precursor 36 are dispersed in the first medium 24 as shown in FIG. 5.

As described so far, in the present embodiment, the halide ions 16H are coordinated to the quantum dots 14 in step S8, and the quantum-dot-dispersed solution 38 containing the quantum dots 14 to which the halide ions 16H are coordinated and the precursor 36 is synthesized in step S10. In other words, step S8 and step S10 are steps for preparing the quantum-dot-dispersed solution 38. In the quantum-dot-dispersed solution 38, the quantum dots 14 are dispersed in a solution containing the precursor 36 to the sulfide semiconductor 16 and the halide ions 16H.

The precursor 36 to the sulfide semiconductor 16 in the quantum-dot-dispersed solution 38 may include, for example, at least one of compounds of metal acetate, metal nitrate, and metal halogen salt as a metal source and at least one of compounds of thiourea, N-methylthiourea, 1,3-dimethylthiourea, N,N′-dimethylthiourea, tetramethylthiourea, and thioacetamide as a sulfur source. Alternatively, the precursor 36 may contain a metal complex in which thiourea, N-methylthiourea, 1,3-dimethylthiourea, N,N′-dimethylthiourea, tetramethylthiourea, or thioacetamide is coordinated to metal atoms.

### Formation of Light-Emitting Layer

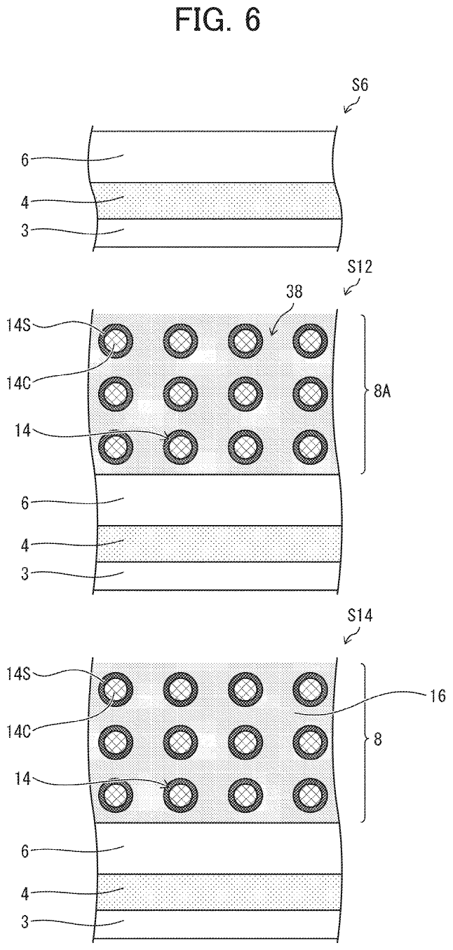

A detailed description is given next of how to apply the quantum-dot-dispersed solution 38 and how to form the light-emitting layer 8 from the quantum-dot-dispersed solution 38, with reference to FIG. 6. FIG. 6 is a step-specific cross-sectional view illustrating a method of forming the light-emitting layer 8.

Referring to FIG. 6, when step S6 is completed, the array substrate 3, the anode 4, and the hole transport layer 6 are already formed. Here, in the present embodiment, the quantum-dot-dispersed solution 38 synthesized in step S8 and step S10 is applied onto the hole transport layer 6 (step S12). In other words, step S12 is a step of applying the quantum-dot-dispersed solution 38 onto a substrate by using a stack body containing the array substrate 3, the anode 4, and the hole transport layer 6 as the substrate. A coating layer 8A containing the quantum-dot-dispersed solution 38 is thus formed on the hole transport layer 6.

The quantum-dot-dispersed solution 38 may be applied, for example, by spin-coating in which the quantum-dot-dispersed solution 38 is applied onto the hole transport layer 6 while rotating the stack body of all the layers from the array substrate 3 through the hole transport layer 6. Alternatively, the quantum-dot-dispersed solution 38 may be applied by an existing thin-film-forming method such as inkjet printing.

Following the application of the quantum-dot-dispersed solution 38, the coating layer 8A is dried by heating the stack body of all the layers from the array substrate 3 through the coating layer 8A at temperatures from 80°° C. to 500° C. for at least 1 minute (step S14). As the coating layer 8A is dried, the precursor 36 is crystallized to form the sulfide semiconductor 16. Hence, the light-emitting layer 8 is formed on the hole transport layer 6 as shown in FIG. 6.

In the quantum-dot-dispersed solution 38, the halide ions 16H are coordinated to the shells 14S of the quantum dots 14. Therefore, the quantum dots 14 exhibits such high dispersibility in polar solvents that the quantum dots 14 are unlikely to precipitate. Furthermore, this high dispersibility restrains the quantum dots 14 from aggregating as a result of the precursor 36 reacting on the surface of the quantum dots 14, thereby retaining the dispersibility of the quantum dots 14 over an extended period.

Furthermore, as the first medium 24 in the quantum-dot-dispersed solution 38 is progressively dried in step S12 to step S14, the concentration of the quantum dots 14 in the quantum-dot-dispersed solution 38 increases. However, since the halide ions 16H are coordinated to the shells 14S of the quantum dots 14 in the quantum-dot-dispersed solution 38, the quantum dots 14 are restrained from precipitating before the precursor 36 is deposited on the hole transport layer 6.

Therefore, the light-emitting layer 8 formed in the present embodiment is a flatter/smoother film in which the quantum dots are dispersed more uniformly. For example, the light-emitting layer 8 in the present embodiment may be formed by the foregoing method so as to have a thickness that has a maximum value less than or equal to twice the minimum value thereof, less than or equal to 1.5 times the minimum value thereof, or less than or equal to 1.2 times the minimum value thereof. In addition, the light-emitting layer 8 may be formed by the foregoing method so as to have a surface-roughness RMS of less than or equal to 3 nm.

In step S14 in accordance with the present embodiment, the stack body of all the layers from the anode 4 through the coating layer 8A is heated to a temperature of from 80° C. to 500° C. to form the light-emitting layer 8. Therefore, all the layers from the anode 4 through the cathode 12 are more preferably composed of a layer of an inorganic material.

Next, the electron transport layer 10 is formed (step S16). The electron transport layer 10 may be formed by for example, vacuum vapor deposition, sputtering, or coating with a colloidal solution as described above. Next, the cathode 12 is formed (step S18). The cathode 12 may be formed by, for example, forming a film of a conductive material by, for example, sputtering as described above.

The light-emitting element 2 in accordance with the present embodiment is hence formed, which completes the manufacture of the light-emitting device 1. Note that the method of manufacturing the light-emitting device 1 in accordance with the present embodiment may include a step of forming the hole injection layer, the electron injection layer, and the intermediate layer described above. Furthermore, following step S18, a capping layer, as an example, may be formed on the cathode 12 to form, for example, this capping layer on the light-emitting element 2.

### Summation of Embodiment 1

The light-emitting layer 8 in the present embodiment contains the at least one quantum dot 14 and the sulfide semiconductor 16 and has a thickness that has a maximum value less than or equal to twice the minimum value thereof, more preferably less than or equal to 1.5 times the minimum value thereof, and most preferably less than or equal to 1.2 times the minimum value thereof. In addition, in the light-emitting layer 8 in the present embodiment, the sulfide semiconductor 16, which is a metal sulfide, includes a continuous film with a 1,000 nm² or greater area in an in-plane direction perpendicular to the thickness direction of the light-emitting layer 8 in a location along this thickness direction. Furthermore, the quantum dots 14 in the light-emitting layer 8 are encased in the sulfide semiconductor 16.

Therefore, the light-emitting element 2 in accordance with the present embodiment includes the light-emitting layer 8 that has a more uniform thickness. The light-emitting layer in a light-emitting element is generally preferably flatter/smoother to reduce local high concentrations of injected carriers and to reduce variations in carrier injection efficiency caused by the location of the light-emitting layer 8. Therefore, the light-emitting element 2, for example, reduces variations in carrier injection efficiency caused by the location of the light-emitting layer 8 and achieves a higher luminous efficiency and an improved life. In addition, the light-emitting layer 8 in accordance with the present embodiment enables protecting the quantum dots 14 with the sulfide semiconductor 16, thereby providing the light-emitting element 2 with high reliability.

The light-emitting layer 8 contains one or more quantum dots 14 per 1,000 nm² in an in-plane direction perpendicular to the thickness direction in a location along the thickness direction. By virtue of this structure, the light-emitting layer 8 has desirable luminescence properties as a light-emitting layer in a light-emitting element.

The light-emitting layer 8 has an average thickness of from 10 nm to 100 nm, both inclusive, and a surface-roughness RMS of less than or equal to 3 nm. By virtue of this structure, the light-emitting layer 8 has more desirable luminescence properties as a light-emitting layer in a light-emitting element.

In the present embodiment, the light-emitting layer 8 contains not more than 5 atom % carbon atoms. By virtue of this structure, a more reliable light-emitting layer can be provided. In the present embodiment, the light-emitting layer 8 contains not less than 1 atom % halogen atoms. By virtue of this structure, a light-emitting layer is provided that has a uniform thickness and that is easy to form.

In the present embodiment, halogen atoms have an average concentration that is higher by at least 10% within 1 nm from the outermost face of the quantum dots 14 than in other locations. The average concentration of halogen atoms within 1 nm from the outermost face of the quantum dots 14 is higher preferably by 10%, more preferably by 50%, and most preferably by 100%, than in other locations. By virtue of this structure, in the step of forming the light-emitting layer 8, the dispersibility of the quantum dots 14 in the quantum-dot-dispersed solution 38 cam be increased, and the light-emitting layer 8 can be formed with a more uniform thickness.

In addition, in in the present embodiment, the sulfide semiconductor 16 has a larger band gap than does the core materials for the quantum dots 14. By virtue of this structure, the light-emitting layer 8 can be provided with an improved luminous efficiency and the capability of restraining the diffusion of excitons from the quantum dots 14 to the sulfide semiconductor 16.

The method of forming the light-emitting layer 8, which is a quantum-dot layer in accordance with the present embodiment, includes a step of applying, to a substrate, the quantum-dot-dispersed solution 38 in which the quantum dots 14 are dispersed in a liquid containing the halide ions 16H and the precursor 36 to the sulfide semiconductor 16. By virtue of this method, the dispersibility of the quantum dots 14 in the quantum-dot-dispersed solution 38 is improved, and the aggregation of the quantum dots 14 in the quantum-dot-dispersed solution 38 is reduced, which enables providing the light-emitting layer 8 with a more uniform thickness.

In the method of forming the light-emitting layer 8 in accordance with the present embodiment, the step of forming the light-emitting layer 8 from the quantum-dot-dispersed solution 38 may include a step of drying the applied quantum-dot-dispersed solution 38. In this step, the substrate onto which the quantum-dot-dispersed solution 38 is applied is heated at temperatures from 80°° C. to 500° C. for at least 1 minute. In this case, the light-emitting layer 8 can be formed more easily and conveniently than, for example, when the light-emitting layer 8 is formed by curing the quantum-dot-dispersed solution 38 under ultraviolet light. In addition, since the sulfide semiconductor 16 can protect the quantum dots 14 in the step of drying the quantum-dot-dispersed solution 38 in the present embodiment, the quantum dots 14 exhibits increased reliability.

The method of forming the light-emitting layer 8 includes a step of treating the quantum dots 14 with the halide ions 16H. This step enables easily and conveniently obtaining the quantum dots 14 to which the halide ions 16H are coordinated. Particularly, the quantum dots 14 to which the halide ions 16H are coordinated are produced in the step of treating the quantum dots 14 with the halide ions 16H in the method of forming the light-emitting layer 8. For example, this step enables easily and conveniently obtaining the quantum dots 14 to which the halide ions 16H are coordinated from the existing quantum dots 14 to which organic ligands containing the carbon chains CC are coordinated.

More specifically, the step of treating the quantum dots 14 with the halide ions 16H is a step pf stirring the first solution, which is a non-polar solution containing at least 0.01 mol/l halide ions, and the second solution, which is a polar solution containing the quantum dots 14. Here, in this step, the first solution and the second solution are stirred at least 1 minute. More specifically, the first solution and the second solution are stirred 1 hour by shaking 10 times per minute while keeping the temperature of the solution at 25° C. Hence, the quantum dots 14 to which the halide ions 16H are coordinated can be more reliably obtained.

In addition, the quantum-dot-dispersed solution 38 contains, as a medium, the first medium 24 containing at least one compound selected from the group consisting of dimethyl sulfoxide (DMSO), N,N-dimethylformamide (DMF), N-methylformamide (NMF), formamide, N,N′-dimethylpropylene urea, dimethylacetamide, N-methylpyrrolidone, γ-butyrolactone, propylene carbonate, acetonitrile, 2-methoxyethanol, methyl acetate, ethyl acetate, ethyl formate, methyl formate, tetrahydrofuran, diethyl ether, tetrahydrothiophene, and diethyl sulfide. The quantum-dot-dispersed solution 38 can be hence synthesized that easily dissolves the halide ions 16H.

Furthermore, the precursor 36 to the sulfide semiconductor 16 may contain a compound selected from metal acetate and metal halogen salt as a metal source and a compound selected from thiourea, N-methylthiourea, 1,3-dimethylthiourea, N,N′-dimethylthiourea, tetramethylthiourea, and thioacetamide as a sulfur source. In addition, the precursor 36 to the sulfide semiconductor 16 may be a metal complex in which thiourea, N-methylthiourea, 1,3-dimethylthiourea, N,N′-dimethylthiourea, tetramethylthiourea, or thioacetamide is coordinated to metal atoms. This specification can enhance the effect of the sulfide semiconductor 16, formed from the precursor 36, providing protection to the quantum dots 14, and the light-emitting layer 8 can be formed with higher reliability.

The method of manufacturing the light-emitting device 1 described in the present embodiment, which is an exemplary method of manufacturing an optical device, includes the aforementioned method of forming the light-emitting layer 8. By this method of manufacturing, the light-emitting device 1 can be manufactured that includes the light-emitting element 2 including the light-emitting layer 8 with improved luminescence properties.

### Quantum-Dot Layer in Accordance With Example

The performance of the light-emitting layer 8 in accordance with the present embodiment was verified as in the following, by comparing the light-emitting layer in accordance with an example of the invention with light-emitting layers in accordance with comparative examples. Note that the present embodiment is not at all limited by the following example of the invention.

### Example 1

CdSe/ZnS quantum dots manufactured by Mesolight were purchased and diluted in octane to a concentration of 1 mg/ml to obtain solution A. Solution A and a 0.2 mol/l DMF solution of zinc chloride were mixed and vigorously stirred while keeping solution A and the DMF solution separated in two layers, and it was then verified that the quantum dots had moved to the lower layer. The transparent upper layer was removed, and toluene was added to the lower layer for precipitation. A quantum-dot-dispersed solution was obtained in which the precipitate was dispersed in a DMF solution of thiourea (0.2 mol/l) and zinc acetate dihydrate (0.2 mol/l).

### Comparative Example 1

Solution A was used as the quantum-dot-dispersed solution.

### Comparative Example 2

Solution A and a 2-methoxyethanol solution of ammonium thiocyanate (0.2 mol/l) and zinc acetate dihydrate (0.2 mol/l) were mixed and vigorously stirred while keeping solution A and the 2-methoxyethanol solution separated in two layers, and it was then verified that the quantum dots had moved to the lower layer. The transparent upper layer was removed, and toluene was added to the lower layer for precipitation. A quantum-dot-dispersed solution was obtained in which the precipitate was dispersed in a 2-methoxyethanol solution of ammonium thiocyanate (0.2 mol/l) and zinc acetate dihydrate (0.2 mol/l).

In Example 1 and in both Comparative Examples, a quantum-dot-dispersed solution prepared so as to achieve a quantum dot (QD) concentration of 15 mg/ml was let to sit for 1 hour, after which an isopropanol solution in which PVP had been dissolved to a concentration of 2 mg/ml was applied to a clean glass substrate at 3,000 rpm. Thereafter, the quantum-dot-dispersed solution was applied to the glass substrate by spin-coating at the rotational speed of 3,000 rpm. In Example 1 and Comparative Example 2, the quantum-dot-dispersed solution on the glass substrate was heated for 30 minutes in a 175° C. nitrogen atmosphere to obtain a light-emitting layer. In Comparative Example 1, the quantum-dot-dispersed solution on the glass substrate was heated for 30 minutes in a 100°° C. nitrogen atmosphere to obtain a light-emitting layer.

TABLE 1

| | Flatness and | Heat Resistance (PLQY |
|---|---|---|
| | Smoothness of Film | after 175° C. annealing) |
| Comparative Example 1 | Good | 45% |
| Comparative Example 2 | Not Good | 55% |
| Example 1 | Good | 60% |

In Table 1, the “Flatness and Smoothness of Film” column shows evaluations of the flatness/smoothness of the light-emitting layers formed in Example and Comparative Examples. The flatness/smoothness of the film was deemed “Good” when the light-emitting layer had a maximum thickness that is less than or equal to twice the minimum thickness thereof and otherwise was deemed “Not Good.” A light-emitting layer in a light-emitting element generally has its current concentration reduced where the thickness is minimum, hence exhibiting desirable properties as a light-emitting layer in a light-emitting element, when the maximum thickness is less than or equal to twice the minimum thickness. The thickness of the light-emitting layer was measured using a stylus profilometer.

In addition, in Table 1, the “Heat Resistance (PLQY after 175° C. annealing)” column shows the quantum yield in photoluminescence mode measured after the light-emitting layer was annealed at 175° C. Therefore, a larger percentage in the “Heat Resistance (PLQY after 175° C. annealing)” column indicates that the luminous efficiency is less likely to decrease even if the light-emitting layer is heated, which in turn indicates higher heat resistance of the light-emitting layer.

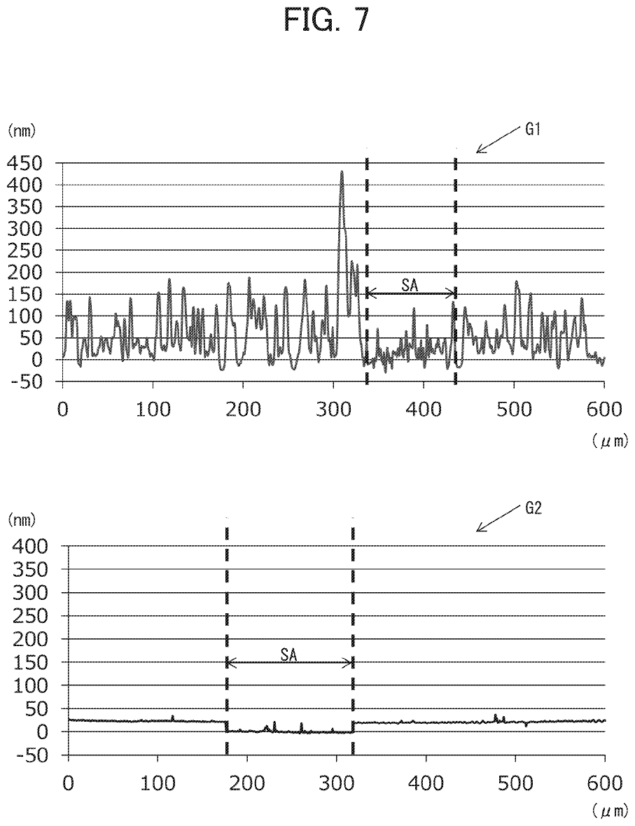

Table 1 shows that the flatness/smoothness of the light-emitting layer of Example 1 and the flatness/smoothness of the light-emitting layer of Comparative Example 1 were deemed “Good,” whereas the flatness/smoothness of the light-emitting layer of Comparative Example 2 was deemed “Not Good.” A description is given particularly of the flatness/smoothness of the light-emitting layer of Example 1 and the light-emitting layer of Comparative Example 2 with reference to FIG. 7. FIG. 7 is a pair of graphs representing the thickness of the light-emitting layer of Example 1 and the thickness of the light-emitting layer of Comparative Example 2. In FIG. 7, graph G1 represents the light-emitting layer of Comparative Example 2, whereas graph G2 represents the light-emitting layer of Example 1. In the graphs in FIG. 7, the horizontal axis indicates a location on a certain straight line on the glass substrate, the vertical axis indicates the thickness of the light-emitting layer in that location, and the scratched areas SA in the graphs in FIG. 7 indicate that the light-emitting layer was removed in the scratched areas SA by scratching, to clearly observe the location of the top face of the glass substrate in the thickness direction of the light-emitting layer.

Graph G1 clearly shows that the light-emitting layer of Comparative Example 2 has almost zero thickness in some locations, but a thickness in excess of 150 nm in many locations and in excess of 400 nm in some locations. Meanwhile, graph G2 clearly shows that the light-emitting layer of Example 1 has an approximately 25-nm thickness in any location. The improvement of the flatness/smoothness of the light-emitting layer in Example 1 over Comparative Example 2 is presumably because halide ions were coordinated to quantum dots in the quantum-dot-dispersed solution used to form the light-emitting layer of Example 1, which kept the quantum dots dispersed and rendered the quantum dots less likely to aggregate.

In addition, Table 1 shows that the light-emitting layer of Example 1 has higher heat resistance than the light-emitting layers of both Comparative Examples and exhibits particularly good heat resistance over the light-emitting layer of Comparative Example 1. This is presumably because the quantum dots in the light-emitting layer of Example 1 were coated with metal sulfide, thereby being restrained from developing surface defects under heat and hence from being degraded.

From the description above, it is concluded that the light-emitting layer of Example 1 has both the flatness/smoothness and the heat resistance improved over the light-emitting layers of both Comparative Examples.

### Embodiment 2

### Display Device

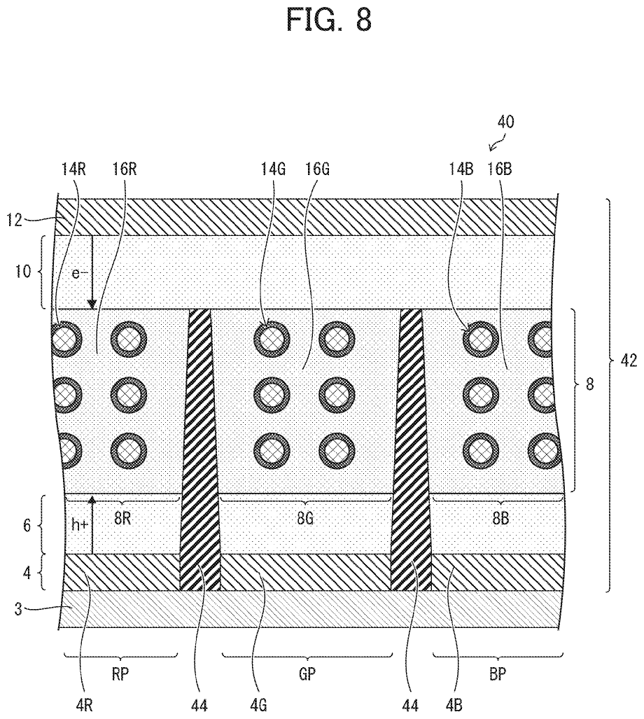

FIG. 8 is a schematic cross-sectional view of a display device 40 as an exemplary optical device in accordance with the present embodiment. The display device 40 in accordance with the present embodiment includes a light-emitting element layer 42 on the array substrate 3. The array substrate 3 may or may not be the same as the array substrate 3 in accordance with the preceding embodiment and may include, for example, TFTs for driving pixel electrodes (detailed later) individually by current.

The light-emitting element layer 42, similarly to the light-emitting element 2 in accordance with the preceding embodiment, includes a hole transport layer 6, a light-emitting layer 8, an electron transport layer 10, and a cathode 12, all of which are provided on an anode 4 in this order when viewed upward. Here, in the present embodiment, the anode 4, the hole transport layer 6, and the light-emitting layer 8 are separated from each other by a bank 44.

In particular, the anode 4 in the present embodiment is divided into an anode 4R, an anode 4G, and an anode 4B by the bank 44. In addition, the hole transport layer 6 is divided into a hole transport layer 6R, a hole transport layer 6G, and a hole transport layer 6B by the bank 44. Furthermore, the light-emitting layer 8 is divided into a red light-emitting layer 8R, a green light-emitting layer 8G, and a blue light-emitting layer 8B by the bank 44. Note that the electron transport layer 10 and the cathode 12 are not divided by the bank 44, but commonly formed. The bank 44 dividing the anode 4 may be formed in such a location as to cover the side faces of the anode 4 and the periphery of the top face of the anode 4 as shown in FIG. 5.

In addition, in the light-emitting element layer 42 in accordance with the present embodiment, a red subpixel RP is formed by the insular anode 4R, hole transport layer 6R, and red light-emitting layer 8R, as well as by the common electron transport layer 10 and cathode 12. Likewise, a green subpixel GP is formed by the insular anode 4G, hole transport layer 6G, and green light-emitting layer 8G, as well as by the common electron transport layer 10 and cathode 12. Likewise, a blue subpixel BP is formed by the insular anode 4B, hole transport layer 6B, and blue light-emitting layer 8B, as well as by the common electron transport layer 10 and cathode 12.

In the present embodiment, the red light-emitting layer 8R in the red subpixel RP emits red light, the green light-emitting layer 8G in the green subpixel GP emits green light, and the blue light-emitting layer 8B in the blue subpixel BP emits blue light. In other words, the light-emitting element layer 42 includes a plurality of subpixels for each emission wavelength of the light-emitting layer 8 and includes the anode 4, the hole transport layer 6, and the light-emitting layer 8 in each subpixel. Note that the light-emitting element layer 42 includes the electron transport layer 10 and the cathode 12 commonly to all the subpixels.

Here, “blue light” refers to, for example, light that has a central emission wavelength in the wavelength range of from 400 nm to 500 nm, both inclusive. In addition, “green light” refers to, for example, light that has a central emission wavelength in the wavelength range of from 500 nm exclusive to 600 nm inclusive. In addition, “red light” refers to, for example, light that has a central emission wavelength in the wavelength range of from 600 nm exclusive to 780 nm inclusive.

In the display device 40 in accordance with the present embodiment, a group of one red subpixel RP, one green subpixel GP, and one blue subpixel BP in the light-emitting element layer 42 constitutes a pixel in the display device 40. In addition, the display device 40 includes a plurality of pixels other than this pixel in in the present embodiment.

The layers in the light-emitting element layer 42 in accordance with the present embodiment may be made of the same material as the layers in the light-emitting element 2 in accordance with the preceding embodiment, except for the light-emitting layer 8. In the present embodiment, the red light-emitting layer 8R contains red quantum dots 14R and a sulfide semiconductor 16R. In addition, the green light-emitting layer 8G contains green quantum dots 14G and a sulfide semiconductor 16G. Furthermore, the blue light-emitting layer 8B contains blue quantum dots 14B and a sulfide semiconductor 16B.

Each quantum dot in the light-emitting layer 8 may have the aforementioned core/shell structure including the core 14C and the shell 14S. In this case, the cores 14C of the quantum dots in the light-emitting layer 8 of a pixel have a particle diameter that varies in accordance with the color of the light to be emitted by the pixel. Quantum dots with a core/shell structure generally exhibit a primary emission wavelength that is proportional to the core diameter. Therefore, the color of the light emitted by the light-emitting layer 8 can be adjusted by controlling the particle diameter of the cores 14C of the quantum dots in the light-emitting layer 8 of the pixels.

The sulfide semiconductors 16 in accordance with the present embodiment contain a material for the sulfide semiconductor 16 in accordance with the preceding embodiment. Here, the sulfide semiconductors 16 in the light-emitting layers 8 of the subpixels may be made of the same material across the subpixels or may be made of different materials from one subpixel to the other.

### Method of Manufacturing Display Device

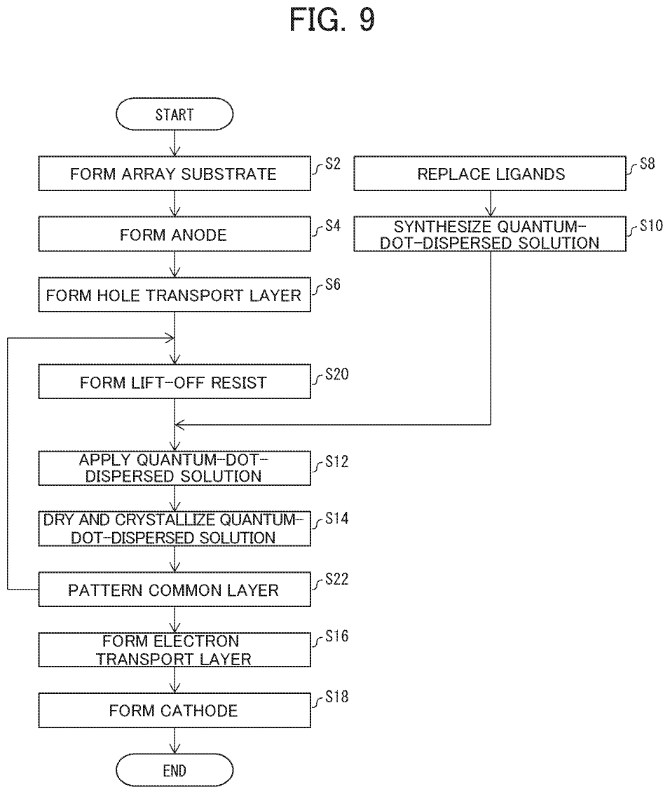

A description is given of a method of manufacturing the display device 40 that is an exemplary method of manufacturing an optical device in accordance with the present embodiment with reference to FIG. 9. FIG. 9 is a flow chart representing a method of manufacturing the display device 40 in accordance with the present embodiment.

In the method of manufacturing the display device 40 in accordance with the present embodiment, first of all, step S2 through step S6 described above are performed. Here, in step S2, the TFTs for driving the subpixels may be formed on the array substrate 3. In addition, in step S4, the anode 4 is formed in each subpixel in an insular manner. Furthermore, in step S6, prior to the formation of the hole transport layer 6, the bank 44 is formed in such a location as to cover the edges of the anodes 4. The bank 44 may be formed by, for example, applying a material containing a photosensitive resin and subsequently patterning this material by photolithography. Step S6 may include a step of removing the hole transport layer 6 on the bank 44; alternatively, the hole transport layer 6 on the bank 44 may be retained as a layer that is common to the subpixels.

### Lift-Off

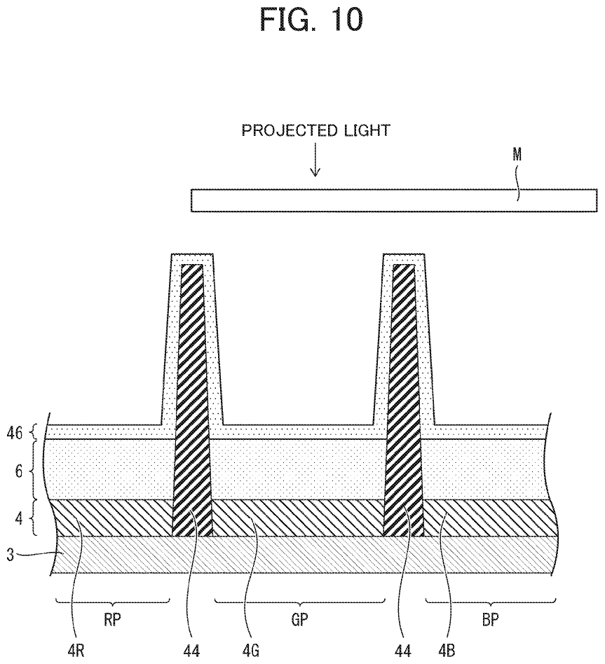

Next, a step of forming the light-emitting layer 8 is performed. A more detailed description is now given of the step of forming the light-emitting layer 8 in accordance with the present embodiment with reference to FIGS. 10 to 13. FIGS. 10 to 13 are step-specific cross-sectional views illustrating the step of forming the light-emitting layer 8 in accordance with the present embodiment and show cross-sections that correspond to the cross-section shown in FIG. 8. Note that FIGS. 10 to 13 illustrate a method of forming the red light-emitting layer 8R as an example.

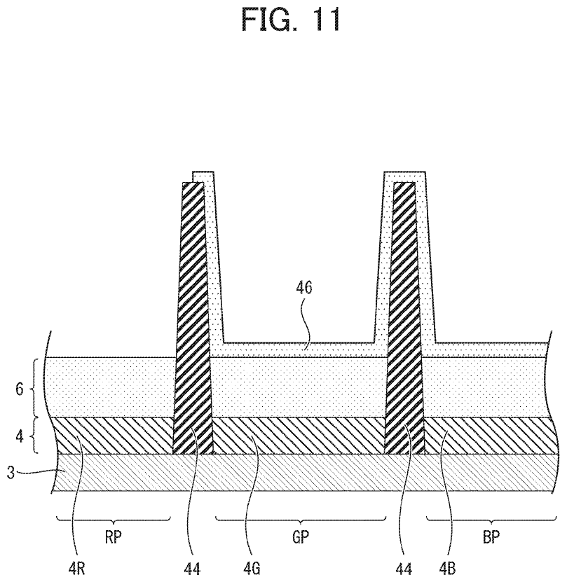

In the step of forming the light-emitting layer 8, first of all, a lift-off resist 46 is formed by patterning as shown in FIGS. 10 and 11 (step S20). The lift-off resist 46 is, for example, a photosensitive resin material and contains, for example, a positive photosensitive material in the present embodiment. In step S20, after a film of the lift-off resist 46 is formed commonly to the plurality of subpixels, a pattern of the lift-off resist 46 is formed in locations other than the location where the red light-emitting layer 8R is to be formed, by exposing to light, and developing, the lift-off resist 46 (by patterning the film of the lift-off resist 46).

For instance, in step S20, first of all, the lift-off resist 46 is formed as a layer overlying the hole transport layer 6 and the bank 44 by, for example, coating as shown in FIG. 10. Next, a photomask M is placed in locations overlapping the green subpixels GP and the blue subpixels BP, excluding the red subpixels RP, above the lift-off resist 46 as shown in FIG. 10.

In this state, light is projected from above the lift-off resist 46 as shown in FIG. 10 to irradiate with light only the lift-off resist 46 placed in locations overlapping the red subpixels RP. Hence, the lift-off resist 46 placed in locations overlapping the red subpixels RP acquires improved solubility in the development solution. Next, the lift-off resist 46 is formed in locations overlapping the green subpixels GP and the blue subpixels BP, excluding the red subpixels RP, as shown in FIG. 11, through patterning by developing the lift-off resist 46 in a suitable development solution. Note that prior to the formation of the lift-off resist 46 by patterning, the applied lift-off resist 46 may be pre-baked.

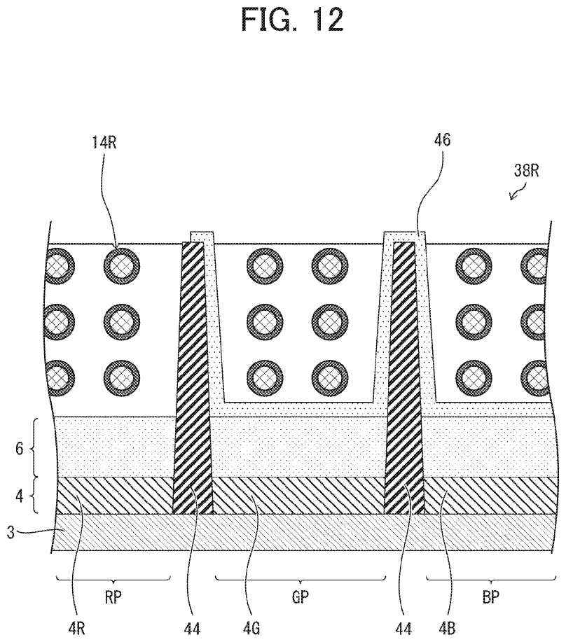

Next, referring to FIG. 12, aforementioned step S12 is performed to apply the quantum-dot-dispersed solution in which the quantum dots are dispersed. Note that aforementioned step S8 and step S10 are performed to synthesize the quantum-dot-dispersed solution before step S12 is performed. FIG. 12 shows the application of the quantum-dot-dispersed solution 38 in which the red quantum dots 14R are dispersed.

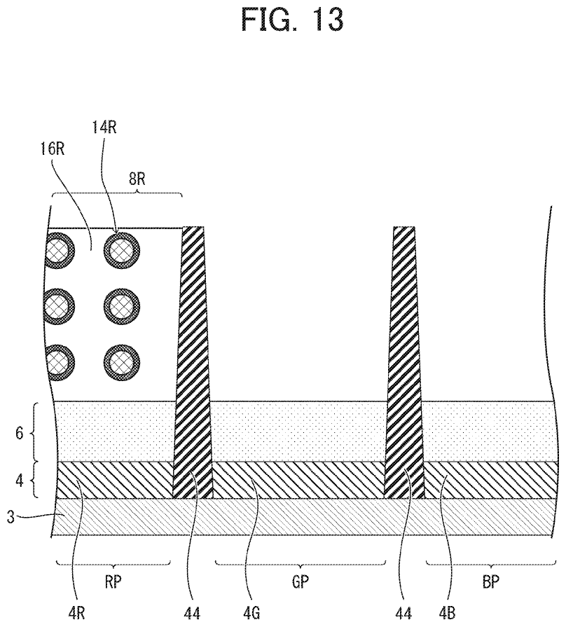

Next, the applied quantum-dot-dispersed solution is dried by the same technique as in aforementioned step S14 to obtain a common layer containing the red quantum dots 14R on the subpixels. Next, the common layer is patterned by removing parts of this common layer by lift-off (step S22). For example, in step S22, the lift-off resist 46 formed by patterning in step S20 is removed using a suitable medium containing, for example, acetone. Hence, the lift-off resist 46 formed in locations overlapping the green subpixel GP and the blue subpixel BP is removed. Here, parts of the common layer formed on this lift-off resist 46 are removed, as well as the lift-off resist 46 is removed. Hence, as shown in FIG. 13, the red quantum dots 14R and the sulfide semiconductor 16 remain only in the red subpixel RP, forming the red light-emitting layer 8R.

Thereafter, step S20, step S12, step S14, and step S22 are repeatedly performed while changing the type of the quantum dots in the quantum-dot-dispersed solution to be applied in step S12 and the locations in which the photomask M is provided in step S20. Here, if the type of the quantum-dot-dispersed solution to be applied in step S12 is changed, step S8 and step S10 may be performed every time the change is made. Hence, the light-emitting layer 8 is formed containing the red light-emitting layer 8R, the green light-emitting layer 8G, and the blue light-emitting layer 8B.

Note that the present embodiment has described a method of patterning each light-emitting layer 8 by lift-off as described above, which is not the only feasible implementation of the invention. Alternatively, for example, in the present embodiment, each light-emitting layer 8 may be patterned by photolithography.

For instance, in step S10 in accordance with the present embodiment, a photosensitive resin material that cures under ultraviolet light may be added to the quantum-dot-dispersed solution 38. In addition, in step S10, a precursor to metal sulfide that decomposes and cures under ultraviolet light may be added as the precursor 36 to the quantum-dot-dispersed solution 38. Next, the quantum-dot-dispersed solution 38 may be applied and dried, and the precursor 36 be crystallized, by the same technique as in step S12 and step S14. Here, in step S14, the quantum-dot-dispersed solution 38 may be partially dried, and the precursor 36 be partially crystallized, by heating the substrate at temperatures from 80° C. to 400° C. for at least 1 minute.

Furthermore, following step S14, a photomask that has portions transparent to ultraviolet light in locations overlapping the red subpixels RP is placed above the quantum-dot-dispersed solution 38. Next, ultraviolet light of a wavelength of from 10 nm to 400 nm is projected to the quantum-dot-dispersed solution 38 through this photomask for at least 1 minute. Hence, only those parts of the quantum-dot-dispersed solution 38 that overlap the red subpixels RP are cured. Finally, development is done in which the uncured quantum-dot-dispersed solution 38 in locations not overlapping the red subpixels RP is removed by rinsing the substrate in a suitable development solution, to form the red light-emitting layers 8R.

Next, step S12, step S14, the projection of ultraviolet light, and development are repeatedly performed while changing the position for ultraviolet light projection. Here, if the type of the quantum-dot-dispersed solution to be applied in step S12 is changed, step S8 and step S10 may be performed every time the change is made. Hence, the light-emitting layer 8 is formed containing the red light-emitting layer 8R, the green light-emitting layer 8G, and the blue light-emitting layer 8B.

The foregoing method enables omitting step S20. In other words, the light-emitting layer 8 can be directly formed by patterning without having to form the lift-off resist 46 for every subpixel by patterning, which simplifies the manufacturing process.

Next, step S16 and step S18 are performed sequentially to form the electron transport layer 10 and the cathode 12. The light-emitting element layer 42 in accordance with the present embodiment is formed in this manner, which completes the manufacture of the display device 40.

The light-emitting element layer 42 in accordance with the present embodiment contains the at least one quantum dot 14 and the sulfide semiconductor 16 and includes the light-emitting layer 8 in which the maximum thickness is less than or equal to twice the minimum thickness. In addition, in the light-emitting layer 8 in each subpixel in accordance with the present embodiment, the sulfide semiconductor 16, which is a metal sulfide, includes a continuous film with a 1,000 nm² or greater area in an in-plane direction perpendicular to the thickness direction of the light-emitting layer 8 in a location along this thickness direction. Furthermore, the quantum dots 14 in the light-emitting layer 8 are encased in the sulfide semiconductor 16. In addition, in the light-emitting layer 8 in each subpixel in accordance with the present embodiment, halogen atoms have an average concentration that is higher by at least 10% within 1 nm from the outermost face of the quantum dots 14 than in other locations.

Therefore, the quantum dots can be protected by the sulfide semiconductor 16, and additionally, the resultant light-emitting element layer 42 includes the light-emitting layer 8 in which the thickness irregularity is reduced. In addition, in the present embodiment, the sulfide semiconductor 16 can protect the quantum dots 14 in the step of patterning the common layer containing the quantum dots 14. Therefore, the degradation of the quantum dots 14 in a development solution can be reduced, which further improves the reliability of the quantum dots 14.

### Embodiment 3

### Wavelength Conversion Layer

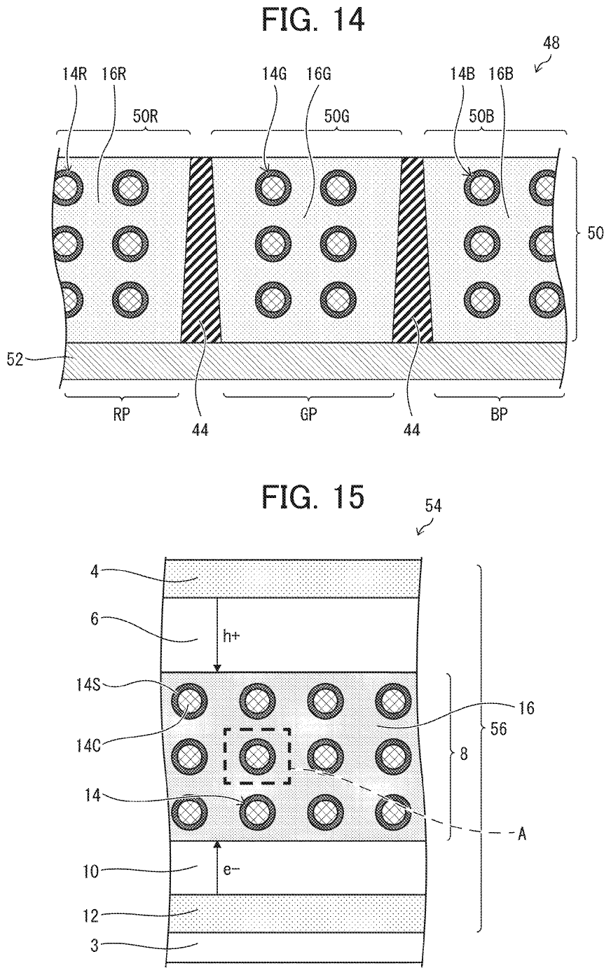

FIG. 14 is a schematic cross-sectional view of a display device 48 that is another exemplary optical device in accordance with the present embodiment. The display device 48 in accordance with the present embodiment includes a wavelength conversion layer 50 on a backlight unit 52 as a light source unit.

The wavelength conversion layer 50 includes a red wavelength conversion layer 50R, a green wavelength conversion layer 50G, and a blue wavelength conversion layer 50B. Here, the red wavelength conversion layer 50R, the green wavelength conversion layer 50G, and the blue wavelength conversion layer 50B have the same structure as the red light-emitting layer 8R, the green light-emitting layer 8G, and the blue light-emitting layer 8B in accordance with the preceding embodiments respectively.

For instance, the red wavelength conversion layer 50R contains the red quantum dots 14R and the sulfide semiconductor 16R, both described earlier. In addition, the green wavelength conversion layer 50G contains the green quantum dots 14G and the sulfide semiconductor 16G, both described earlier. Furthermore, the blue wavelength conversion layer 50B contains the blue quantum dots 14B and the sulfide semiconductor 16B, both described earlier. In other words, the wavelength conversion layer 50 in accordance with the present embodiment is a quantum-dot layer.

The red wavelength conversion layer 50R, the green wavelength conversion layer 50G, and the blue wavelength conversion layer 50B are all divided by the bank 44 formed on the backlight unit 52 (detailed later). The display device 48 includes the red subpixel RP in a location overlapping the red wavelength conversion layer 50R in a plan view of the backlight unit 52. Likewise, the display device 48 includes the green subpixel GP and the blue subpixel BP in respective locations overlapping the green wavelength conversion layer 50G and the blue wavelength conversion layer 50B in a plan view of the backlight unit 52.

The backlight unit 52 is a light source unit for projecting light onto the wavelength conversion layer 50. The backlight unit 52 projects, for example, ultraviolet light individually onto the red wavelength conversion layer 50R, the green wavelength conversion layer 50G, and the blue wavelength conversion layer 50B. Therefore, the wavelength conversion layer 50 in each subpixel onto which the backlight unit 52 has projected ultraviolet light emits light by the quantum dots 14 contained therein absorbing this ultraviolet light and reemitting light. Therefore, the display device 48 serves as a display device including the red subpixels RP, the green subpixels GP, and the blue subpixels BP as pixels.

The display device 48 in accordance with the present embodiment may be manufactured by a manufacturing method that is the same, except for some changes, as the method of manufacturing the display device 40 in accordance with the preceding embodiments. For example, in the method of manufacturing the display device 40 in accordance with the present embodiment, first of all, a step of preparing the backlight unit 52 is performed in place of step S2 in accordance with the preceding embodiments. Next, the bank 44 is formed on the backlight unit 52 by the same method as the method described in the preceding embodiments. Next, the wavelength conversion layer 50 is formed by the same method as the method of forming the light-emitting layer 8 in accordance with the preceding embodiments. The display device 48 may be manufactured in this manner. Alternatively, the display device 48 may be manufactured by stacking, on the backlight unit 52, the wavelength conversion layer 50 formed on a substrate that is separately prepared.

The wavelength conversion layer 50 in accordance with the present embodiment contains the at least one quantum dot 14 and the sulfide semiconductor 16 and has a thickness that has a maximum value less than or equal to twice the minimum value thereof. In addition, in the wavelength conversion layer 50 in each subpixel in accordance with the present embodiment, the sulfide semiconductor 16, which is a metal sulfide, includes a continuous film with a 1,000 nm² or greater area in an in-plane direction perpendicular to the thickness direction of the wavelength conversion layer 50 in a location along this thickness direction. Furthermore, the quantum dots 14 in the wavelength conversion layer 50 are encased in the sulfide semiconductor 16. In addition, in the wavelength conversion layer 50 in each subpixel in accordance with the present embodiment, halogen atoms have an average concentration that is higher by at least 10% within 1 nm from the outermost face of the quantum dots 14 than in other locations.

Therefore, the quantum dots 14 can be protected by the sulfide semiconductor 16, and additionally, the resultant wavelength conversion layer 50 has reduced thickness irregularity. In addition, in the present embodiment, the sulfide semiconductor 16 can protect the quantum dots 14 in the step of patterning the common layer containing the quantum dots 14. Therefore, the degradation of the quantum dots 14 in a development solution can be reduced, which further improves the reliability of the quantum dots 14.

### Embodiment 4

### Light-Emitting Element With Inverted Structure

FIG. 15 is a schematic cross-sectional view of a light-emitting device that is another exemplary optical device in accordance with an embodiment of the present invention. Referring to FIG. 15, a light-emitting device 54 in accordance with the present embodiment includes a light-emitting element 56 and an array substrate 3. The light-emitting element 56 includes an electron transport layer 10, a light-emitting layer 8, a hole transport layer 6, and an anode 4 as a second electrode, all of which are provided on a cathode 12 as a first electrode in this order when viewed upward. The cathode 12 of the light-emitting element 2 provided in a layer overlying the array substrate 3 is electrically connected to a TFT on the array substrate 3.

The anode 4, the hole transport layer 6, the light-emitting layer 8, the electron transport layer 10, and the cathode 12, all included in the light-emitting element 56, have the same structure as the anode 4, the hole transport layer 6, the light-emitting layer 8, the electron transport layer 10, and the cathode 12 in the light-emitting element 2 in accordance with Embodiment 1 respectively, except for the order in which the layers are stacked.

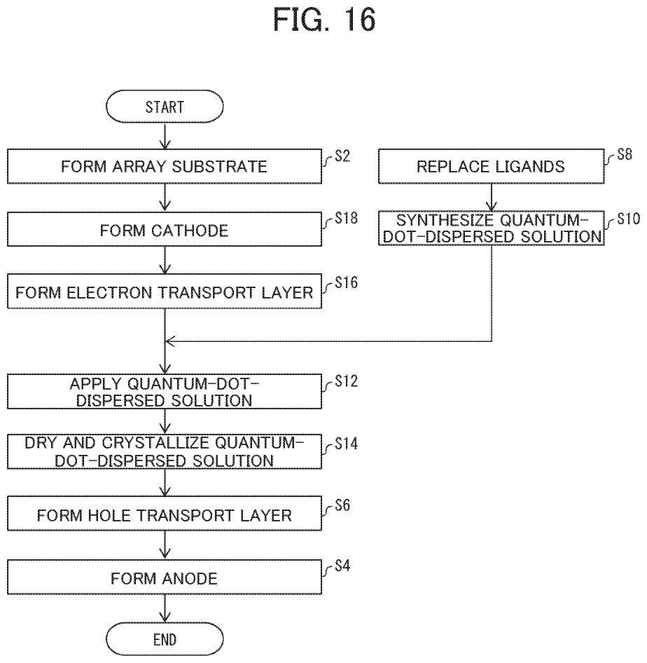

A description is now given of a method of manufacturing the light-emitting device 54 that is an exemplary method of manufacturing an optical device in accordance with the present embodiment with reference to FIG. 16. FIG. 16 is a flow chart representing a method of manufacturing the light-emitting device 54 in accordance with the present embodiment.

In the method of manufacturing the light-emitting device 54 in accordance with the present embodiment, first of all, the array substrate 3 is formed by the same technique as in aforementioned step S2. Next, the cathode 12 is formed on the array substrate 3. The method of forming the cathode 12 in accordance with the present embodiment may be the same method as in aforementioned step S18, except that the cathode 12 is formed on the array substrate 3. Next, the electron transport layer 10 is formed on the cathode 12. The method of forming the electron transport layer 10 in accordance with the present embodiment may be the same method as in aforementioned step S16, except that the electron transport layer 10 is formed on the cathode 12.

In the present embodiment, the quantum-dot-dispersed solution 38 is synthesized by the same method as aforementioned step S8 and step S10 before the completion of step S16. In the present embodiment, the quantum-dot-dispersed solution 38 is applied onto the electron transport layer 10 after step S16 and step S10. In accordance with the present embodiment, the quantum-dot-dispersed solution 38 may be applied by the same method as in aforementioned step S12, except that the quantum-dot-dispersed solution 38 is applied onto the electron transport layer 10. Next, the quantum-dot-dispersed solution 38 is dried, and the precursor 36 to the sulfide semiconductor 16 in the quantum-dot-dispersed solution 38 is crystallized. In accordance with the present embodiment, the quantum-dot-dispersed solution 38 may be dried, and the precursor 36 be crystallized, by the same method as in aforementioned step S14, except that the substrate including the array substrate 3, the cathode 12, and the electron transport layer 10 and the quantum-dot-dispersed solution 38 on this substrate are heated.

Next, the hole transport layer 6 is formed on the light-emitting layer 8. The hole transport layer 6 in accordance with the present embodiment may be formed by the same method as in aforementioned step S6, except that the hole transport layer 6 is formed on the light-emitting layer 8. Next, the anode 4 is formed on the hole transport layer 6. The anode 4 in accordance with the present embodiment may be formed by the same method as in aforementioned step S4, except that the anode 4 is formed on the hole transport layer 6. The light-emitting device 54 in accordance with the present embodiment is manufactured in this manner.

The light-emitting element 56 in accordance with the present embodiment contains the at least one quantum dot 14 and the sulfide semiconductor 16 and includes the light-emitting layer 8 in which the maximum thickness is less than or equal to twice the minimum thickness. In addition, in the light-emitting layer 8 in the present embodiment, the sulfide semiconductor 16, which is a metal sulfide, includes a continuous film with a 1,000 nm² or greater area in an in-plane direction perpendicular to the thickness direction of the light-emitting layer 8 in a location along this thickness direction. Furthermore, the quantum dots 14 in the light-emitting layer 8 are encased in the sulfide semiconductor 16. In addition, in the light-emitting layer 8 in accordance with the present embodiment, halogen atoms have an average concentration that is higher by at least 10% within 1 nm from the outermost face of the quantum dots 14 than in other locations.

Therefore, the quantum dots 14 can be protected by the sulfide semiconductor 16, and additionally, the resultant light-emitting element 56 includes the light-emitting layer 8 in which the thickness irregularity is reduced. In addition, the light-emitting device 54 in accordance with the present embodiment includes the light-emitting element 56 including the cathode 12 on the array substrate 3 side. Therefore, for example, the anode 4 can be formed using a suitable transparent conductive material for the anode 4 in comparison with the material for the cathode 12, in the manufacture of the light-emitting element 56. In such a case, for example, since the light from the light-emitting layer 8 can be extracted on the anode 4 side, the resultant light-emitting device 54 allows the light from the light-emitting layer 8 to be extracted without having to consider the structure of the array substrate 3.

### Supplementary Description

Embodiments 2 and 3 above describe a structure in which the light-emitting element or the wavelength conversion layer formed in one subpixel in a pixel emits light of a specific color. However, this is not the only feasible implementation of the invention; alternatively, each light-emitting element or each wavelength conversion layer may emit white light, and a color filter formed for each subpixel may convert the white light to light of a specific color.

In such a case, the light-emitting layer 8 in the display device 40 in accordance with Embodiment 2 and the wavelength conversion layer 50 in the display device 48 in accordance with Embodiment 3 may include all quantum dots 14 that emit red, green, and blue light. In addition, the wavelength conversion layer 50 in the display device 48 in accordance with Embodiment 3 may include quantum dots 14 that emit red and green light, and the backlight unit 52 may emit blue light. In such a case, the display device 48 may not include the wavelength conversion layer 50 in a blue subpixel PB.

In addition, the light-emitting device 1 in accordance with Embodiment 1, the display device 40 in accordance with Embodiment 2, and the light-emitting device 54 in accordance with Embodiment 4 include a light-emitting element, which is an optical element. Here, the optical element in the present specification is not limited to the aforementioned light-emitting elements.

For instance, the optical element in the present specification may be a photovoltaic cell element including a quantum-dot layer having the same structure as the foregoing light-emitting layer 8 between a pair of electrodes. For example, in this photovoltaic cell element, the quantum dots 14 may generate, from the light incident to the quantum-dot layer, holes and electrons that are transported to respective electrodes to generate electromotive force. In addition, the optical element in the present specification may be an optical sensor including the same stack body as this photovoltaic cell element, in other words, may be a sensor for detecting whether or not light of a specific wavelength has entered the quantum-dot layer, according to whether or not the electromotive force has been generated. Furthermore, the optical device in the present specification is not limited to a light-emitting device including a light-emitting element or to a display device including a light-emitting element and may be an optical device including, for example, the aforementioned photoelectronic element or the aforementioned optical sensor.

The present invention is not limited to the description of the embodiments above and may be altered within the scope of the claims. Embodiments based on a proper combination of technical means disclosed in different embodiments are encompassed in the technical scope of the present invention. Furthermore, new technological features can be created by combining different technical means disclosed in the embodiments.

### REFERENCE SIGNS LIST

1 Light-emitting device (Optical device)
2 Light-emitting element (Optical element)
4 Anode (First electrode)
8 Light-emitting layer (Quantum-dot layer)
12 Cathode (Second electrode)
14 Quantum dot
16 Sulfide semiconductor (Metal sulfide)
16H Halide ion
36 Precursor (to sulfide semiconductor)
38 Quantum-dot-dispersed solution
40, 48 Display device
50 Wavelength conversion layer (Quantum-dot layer)
52 Backlight unit (Light source unit)

1. A method of forming a quantum-dot layer containing at least one quantum dot and a metal sulfide, the method comprising:
a step of preparing a quantum-dot-dispersed solution in which the at least one quantum dot is dispersed in a liquid containing halide ions and a precursor to the metal sulfide; and
a step of applying the quantum-dot-dispersed solution to a substrate.

2. The method according to claim 1, further comprising, after the step of applying the quantum-dot-dispersed solution to the substrate, a step of heating the substrate at a temperature of from 80°° C. to 500° C. for at least 1 minute.

3. The method according to claim 1, further comprising, after the step of applying the quantum-dot-dispersed solution to the substrate:
a step of heating the substrate at a temperature of from 80° C. to 400° C. for at least 1 minute; and
a step of projecting light of a wavelength of from 10 nm to 400 nm onto the quantum-dot-dispersed solution for at least 1 minute.

4. The method according to claim 1, wherein the step of preparing the quantum-dot-dispersed solution comprises a step of treating the at least one quantum dot with the halide ions.

5. The method according to claim 4, wherein in the step of treating the at least one quantum dot with the halide ions, the at least one quantum dot to which the halide ions are coordinated is produced.

6. The method according to claim 4, wherein in the step of treating the at least one quantum dot with the halide ions, a non-polar solution containing the at least one quantum dot and a polar solution containing the halide ions in at least 0.01 mol/l are stirred for at least 1 minute.

7. The method according to claim 1, wherein the quantum-dot-dispersed solution includes, as a medium, at least one compound selected from the group consisting of dimethyl sulfoxide (DMSO), N,N-dimethylformamide (DMF), N-methylformamide (NMF), formamide, N,N′-dimethylpropylene urea, dimethylacetamide, N-methylpyrrolidone, y-butyrolactone, propylene carbonate, acetonitrile, 2-methoxyethanol, methyl acetate, ethyl acetate, ethyl formate, methyl formate, tetrahydrofuran, diethyl ether, tetrahydrothiophene, and diethyl sulfide.

8. The method according to claim 1, wherein the precursor to the metal sulfide contains a compound selected from metal acetate, metal nitrate, and metal halogen salt as a metal source and a compound selected from thiourea, N-methylthiourea, 1,3-dimethylthiourea, N,N′-dimethylthiourea, tetramethylthiourea, and thioacetamide as a sulfur source.

9. The method according to claim 1, wherein the precursor to the metal sulfide is a metal complex in which thiourea, N-methylthiourea, 1,3-dimethylthiourea, N,N′-dimethylthiourea, tetramethylthiourea, or thioacetamide is coordinated to metal atoms.

10. The method according to claim 1, wherein the precursor to the metal sulfide is a precursor to zinc sulfide.

11. A quantum-dot layer comprising:
a continuous metal sulfides film with a 1,000 nm² or greater area in an in-plane direction perpendicular to a thickness direction of the quantum-dot layer in a location along the thickness direction; and
at least one quantum dot encased in the metal sulfide and having a different composition than the metal sulfide, wherein
the quantum-dot layer has a thickness that has a maximum value less than or equal to twice a minimum value of the thickness.

12. The quantum-dot layer according to claim 11 containing at least one of the at least one quantum dot per 1,000 nm² in an in-plane direction perpendicular to the thickness direction in a location along the thickness direction.

13. The quantum-dot layer according to claim 11, wherein the quantum-dot layer has an average thickness of from 10 nm to 100 nm, both inclusive, and a surface-roughness RMS of less than or equal to 3 nm.

14. The quantum-dot layer according to claim 11 containing 5 atom % or fewer carbon atoms.

15. The quantum-dot layer according to claim 11 containing 1 atom % or more halogen atoms.

16. A quantum-dot layer comprising: at least one quantum dot; a metal sulfide; and halogen atoms, wherein the halogen atoms have an average concentration that is higher by at least 10% within 1 nm from an outermost face of the at least one quantum dot than in other locations.

17. The quantum-dot layer according to claim 11, wherein the metal sulfide has a larger band gap than does a core material for the at least one quantum dot.

18. The quantum-dot layer according to claim 11, wherein the metal sulfide is zinc sulfide.

19. An optical element comprising:
a first electrode;
the quantum-dot layer according to claim 11; and
a second electrode, all of which are provided in a stated order.

20. (canceled)

21. A light-emitting device comprising:
the quantum-dot layer according to claim 11; and
a light source unit configured to project light to the quantum-dot layer.
